(19) United States
(12) Patent Application Publication
(10) Pub. No.: US 2025/0172626 A1
(43) Pub. Date: May 29, 2025

(54) APPARATUS AND METHOD FOR MANAGING A BATTERY

(71) Applicants: HYUNDAI MOTOR COMPANY, Seoul (KR); KIA CORPORATION, Seoul (KR)

(72) Inventors: Young Hwa Park, Hwaseong-si (KR); Ki Seon Ryu, Hwaseong-si (KR)

(73) Assignees: HYUNDAI MOTOR COMPANY, Seoul (KR); KIA CORPORATION, Seoul (KR)

(21) Appl. No.: 18/882,421

(22) Filed: Sep. 11, 2024

(30) Foreign Application Priority Data
Nov. 27, 2023 (KR) 10-2023-0166996

(51) Int. Cl. G01R 31/392; G01R 31/367; G01R 31/3842

(52) U.S. Cl. CPC G01R 31/392; G01R 31/367; G01R 31/3842

(57) ABSTRACT

Disclosed are an apparatus for managing a battery and a method thereof. The apparatus includes a sensor that measures a current of the battery, and a processor that is connected to the sensor to determine whether the battery is defective. The processor may obtain a charging current value per unit time through the sensor during a diagnosis period during which the battery is charged, obtain a current representative value of the charging current values, and determine whether the battery is defective based on the current representative value.

### CROSS-REFERENCE TO RELATED APPLICATION

This application claims the benefit of and priority to Korean Patent Application No. 10-2023-0166996, filed in the Korean Intellectual Property Office on Nov. 27, 2023, the entire contents of which are incorporated herein by reference.

### TECHNICAL FIELD

The present disclosure relates to an apparatus for managing a battery and a method thereof, and more particularly, to a technology for determining an abnormal state of a battery.

### BACKGROUND

The statements in this section merely provide background information related to the present disclosure and may not constitute prior art.

Due to the diversity of electronic devices, the field of use of batteries has increased, and recently, the use of batteries has increased with the emergence of electric vehicles or hybrid vehicles.

Battery defects may occur due to deterioration due to use or shock from the outside, and deterioration of battery performance due to defects may adversely affect not only vehicle performance but also safety. Therefore, the importance of technology for determining whether a battery is defective has increased.

In general, because abnormalities in a battery are diagnosed after charging the battery, the battery charging time is regularly included in the process of diagnosing the battery.

In addition, some of the batteries with deteriorated performance may be restored to a normal state depending on the cause of the performance deterioration, but conventionally, it is not possible to distinguish between batteries that may be restored to a normal state. Therefore, a battery that may be restored to a normal state is diagnosed as defective, so that the battery is wasted unnecessarily.

### SUMMARY

The present disclosure has been made to solve the above-mentioned problems occurring in the prior art while advantages achieved by the prior art are maintained intact.

An aspect of the present disclosure provides an apparatus for managing a battery capable of reducing battery diagnosis time and a method thereof.

In addition, another aspect of the present disclosure provides an apparatus for managing a battery capable of reducing battery waste by detecting a normal battery whose charging performance may be restored, and a method thereof.

The technical problems to be solved by the present disclosure are not limited to the aforementioned problems, and any other technical problems not mentioned herein should be clearly understood from the following description by those having ordinary skill in the art to which the present disclosure pertains.

According to an aspect of the present disclosure, an apparatus for managing a battery includes: a sensor device that measures a current of the battery, and a processor that is connected to the sensor device to determine whether the battery is defective. The processor may obtain a charging current value per unit time through the sensor device during a diagnosis period during which the battery is charged. In particular, the processor is configured to obtain a current representative value of the charging current values, and determine whether the battery is defective based on the current representative value.

According to an embodiment, the processor may receive battery state information from the sensor device, and obtain the charging current value corresponding to the battery state information meeting a battery diagnosis condition.

According to an embodiment, the battery state information may include battery charging history information, and the processor may obtain the charging current value when a number of consecutive charging times of the battery in the charging history information is less than a reference number.

According to an embodiment, the battery state information may include state of charge (SOC) of the battery, and the processor may obtain the charging current value when the remaining capacity value of the battery is less than or equal to a reference value.

According to an embodiment, the battery state information may include a measured voltage of the battery, and the processor may obtain the charging current value when the measured voltage of the battery is greater than or equal to a reference voltage.

According to an embodiment, the processor may obtain an average value, a minimum value, or a maximum value of the charging current as the current representative value.

According to an embodiment, the processor may determine that the battery is in a normal state based on the current representative value, particularly when the current representative value is greater than or equal to a threshold value.

According to an embodiment, the processor may determine a rate of change of the charging current value in the diagnosis period when the current representative value being is than the threshold value, and determine whether to perform a re-diagnosis based on the rate of change of the charging current value.

According to an embodiment, the processor may determine whether to perform the re-diagnosis based on that the rate of change of the charging current value is a positive number.

According to an embodiment, the processor may perform the re-diagnosis within a preset limited number of times, and determine that the battery is in a defective state based on the current representative value obtained within the limited number of times, particularly when the current representative value is less than the threshold value.

According to another aspect of the present disclosure, a method of managing a battery includes: obtaining, by a processor, a charging current value per unit time through a sensor device during a diagnosis period during which the battery is charged; determining, by the processor, a current representative value of the charging current values; and determining, by the processor, whether the battery is defective based on the current representative value.

According to an embodiment, the obtaining of the charging current value may include: receiving battery state information from the sensor device, and obtaining the charging current value corresponding to the battery state information meeting a battery diagnosis condition.

According to an embodiment, the battery state information may include battery charging history information. The obtaining of the charging current value may include: confirming a number of consecutive charging times of the battery from the charging history information, and obtaining the charging current value corresponding to the number of consecutive charging times of the battery being less than a reference number.

According to an embodiment, the battery state information may include a SOC of the battery, and the obtaining of the charging current value may be performed corresponding to the remaining capacity value of the battery being less than or equal to a reference value.

According to an embodiment, the battery state information may include a measured voltage of the battery, and the obtaining of the charging current value may be performed corresponding to the measured voltage of the battery being greater than or equal to a reference voltage.

According to an embodiment, the obtaining of the current representative value of the charging current values may include obtaining an average value, a minimum value, or a maximum value of the charging current as the current representative value.

According to an embodiment, the determining of whether the battery is defective may include determining that the battery is normal based on the current representative value being greater than or equal to a threshold value.

According to an embodiment, the determining of whether the battery is defective may include determining a rate of change of the charging current value in the diagnosis period corresponding to the current representative value being less than the threshold value, and determining whether to perform a re-diagnosis based on the rate of change of the charging current value.

According to an embodiment, the determining of whether to perform the re-diagnosis may include determining whether to perform the re-diagnosis based on that the rate of change of the charging current value is a positive number.

According to an embodiment, the determining of whether to perform a re-diagnosis may include performing the re-diagnosis within a preset limited number of times, and determining that the battery is in a defective state based on the current representative value obtained within the limited number of times being less than the threshold value.

### BRIEF DESCRIPTION OF THE DRAWINGS

The above and other objects, features and advantages of the present disclosure should be more apparent from the following detailed description taken in conjunction with the accompanying drawings:

FIG. 1 is a block diagram illustrating the connection relationship of an apparatus for managing a battery according to an embodiment of the present disclosure;

FIG. 2 is a diagram illustrating the configuration of an apparatus for managing a battery according to an embodiment of the present disclosure;

FIG. 3 is a flowchart illustrating a method of managing a battery according to an embodiment of the present disclosure;

FIG. 4 is a flowchart illustrating a battery diagnosis condition according to an embodiment of the present disclosure;

FIG. 5 is a diagram illustrating the changes in charging currents of a normal battery and a defective battery;

FIG. 6 is a diagram illustrating a method of detecting an activatable battery;

FIG. 7 is a flowchart illustrating a method of managing a battery according to another embodiment of the present disclosure;

FIG. 8 is a flowchart illustrating a battery management method according to another embodiment of the present disclosure; and

FIG. 9 is a block diagram illustrating a computing system according to an embodiment of the present disclosure.

### DETAILED DESCRIPTION

Hereinafter, some embodiments of the present disclosure are described in detail with reference to the exemplary drawings. In adding the reference numerals to the components of each drawing, it should be noted that the identical or equivalent component is designated by the identical numeral even when they are displayed on other drawings. Further, in describing the embodiment of the present disclosure, a detailed description of the related known configuration or function has been omitted when it is determined that it interferes with the understanding of the embodiment of the present disclosure.

In addition, terms, such as first, second, A, B, (a), (b) or the like may be used herein when describing components of the present disclosure. The terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those having ordinary skill in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure.

When a component, device, element, or the like of the present disclosure is described as having a purpose or performing an operation, function, or the like, the component, device, or element should be considered herein as being “configured to” meet that purpose or to perform that operation or function.

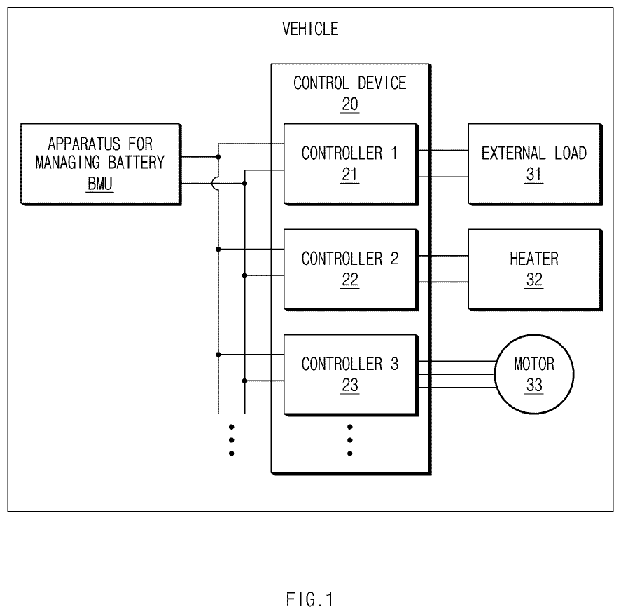

Hereinafter, embodiments of the present disclosure are described in detail with reference to FIGS. 1 to 9.

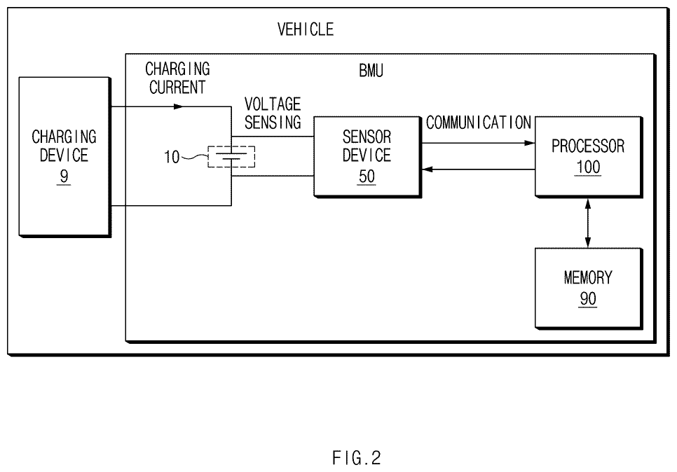

FIG. 1 is a block diagram illustrating the connection relationship of an apparatus for managing a battery according to an embodiment of the present disclosure. FIG. 2 is a diagram illustrating the configuration of an apparatus for managing a battery according to an embodiment of the present disclosure.

Referring to FIG. 1, an apparatus “BMU” for managing a battery according to an embodiment of the present disclosure may be mounted on a vehicle “VEH” and provide a voltage to a control device 20 within the vehicle VEH. The control device 20 may include a plurality of controllers 21, 22, and 23, and each of the controllers 21, 22, and 23 may be connected to electrical components. For example, the first controller 21 may be connected to an external load 31. The second controller 22 may include a DC/DC converter for providing a voltage to a heater 32. The third controller 23 may include a DC/AC converter for providing a voltage to a motor 33 that drives the vehicle.

Referring to FIG. 2, the apparatus BMU for managing a battery according to an embodiment of the present disclosure may include a battery 10, a sensor device 50, a processor 100, and a memory 90.

The battery 10 may include a plurality of battery modules. Each battery module may include a plurality of battery cells.

The battery 10 may be charged through a charging device. A charging device 9 may be an alternator or a low voltage DC-DC converter (LDC).

The sensor device 50 may measure the charging current of the battery 10 and obtain state information of the battery 10. The sensor device 50 may be implemented as a cell monitoring unit that corresponds one-to-one to each battery module.

The processor 100 may be connected to the sensor device 50 and determine whether the battery 10 is defective based on data provided from the sensor device 50.

The processor 100 may obtain a charging current value per unit time through the sensor device 50 during a diagnosis period during which the battery 10 is charged. The diagnosis period may be a period of acquiring the charging current of the battery 10, and may be performed while the battery is charged. Therefore, although operations S320 and S330, which are described below, are performed after charging of the battery 10 is completed. An operation S310 may be performed while charging the battery 10. Based on the charging current value, the processor 100 may obtain a current representative value indicating the magnitude of the charging current during the diagnosis period. In addition, the processor 100 may determine whether the battery 10 is defective based on the current representative value.

The algorithm for operating the processor 100 may be stored in the memory 90. The memory 90 may include a hard disk drive, a flash memory, an electrically erasable programmable read-only memory (EEPROM), a static RAM (SRAM), a ferro-electric RAM (FRAM), a phase-change RAM (PRAM), a magnetic RAM (MRAM), a dynamic random access memory (DRAM), a synchronous dynamic random access memory (SDRAM), a double date rate-SDRAM (DDR-SDRAM), and the like.

In addition, the sensor device 50 and the processor 100 may be connected by a wired or wireless communication device. For example, the processor 100 may be connected to the sensor device 50 by using at least one short-range communication among Bluetooth, radio frequency identification (RFID), infrared data association (IrDA), ultra wideband (UWB), ZigBee, near field communication (NFC), wireless-fidelity (Wi-Fi), Wi-Fi direct, and wireless universal serial bus (USB) technologies.

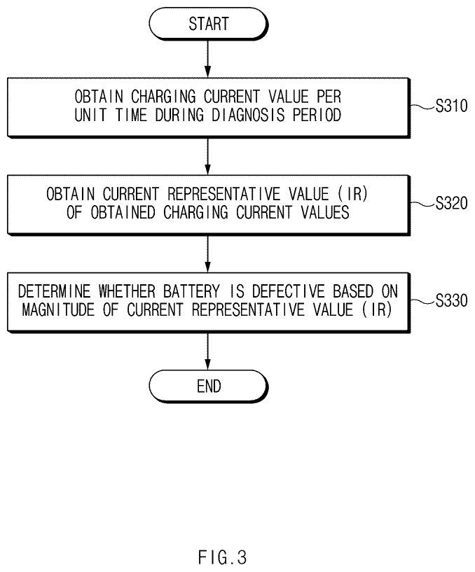

FIG. 3 is a flowchart illustrating a method of managing a battery according to an embodiment of the present disclosure. FIG. 3 illustrates a procedure for determining whether a battery is defective, and the procedures shown in FIG. 3 may be controlled by a processor. Hereinafter, a method of managing a battery according to an embodiment of the present disclosure is described with reference to FIG. 3.

In operation S310, the processor 100 may obtain the charging current value during the diagnosis period of the battery 10.

To this end, the sensor device 50 may measure the charging current provided to the battery 10 while the battery 10 is charged. The processor 100 may receive the charging current from the sensor device 50 and obtain the charging current value per unit time.

The diagnosis period may be set in advance. The diagnosis period may vary depending on the battery 10, and may be set to a time during which the magnitude of the charging current of a normal battery is easily distinguished from that of the charging current of a defective battery based on charging. The diagnosis period may be determined experimentally and may be set to, for example, 15 minutes.

The unit time may be set to a time shorter than the diagnosis period, and may be set to a time in which a change in the magnitude of the charging current does not appear suddenly.

For example, the unit time may be set to 1 minute.

In operation S320, the processor 100 may obtain a current representative value based on the charging current value.

A current representative value “Ir” may be used to indicate the magnitude of the charging current in the diagnosis period.

The current representative value Ir may be an average value of charging current values. For example, when 15 charging current values are obtained during the diagnosis period, the processor 100 may obtain the current representative value Ir by averaging the 15 charging current values.

The current representative value may be the minimum value of the charging current values. When the minimum value among the 15 charging current values is 14 A, the processor 100 may determine the current representative value Ir as 14.

The current representative value may be the maximum value of the charging current values. When the maximum value among the 15 charging current values is 17 A, the processor 100 may determine the current representative value Ir as 17.

In operation S330, the processor 100 may determine whether the battery is defective based on the magnitude of the current representative value Ir.

For example, the processor 100 may determine that the battery 10 is normal based on the fact that the magnitude of the current representative value Ir is greater than or equal to a preset threshold value. Alternatively, the processor 100 may determine that the battery 10 is defective or may perform a re-diagnosis based on the fact that the magnitude of the current representative value Ir is less than the threshold value. A specific example of the procedure for determining whether a battery is defective is described below.

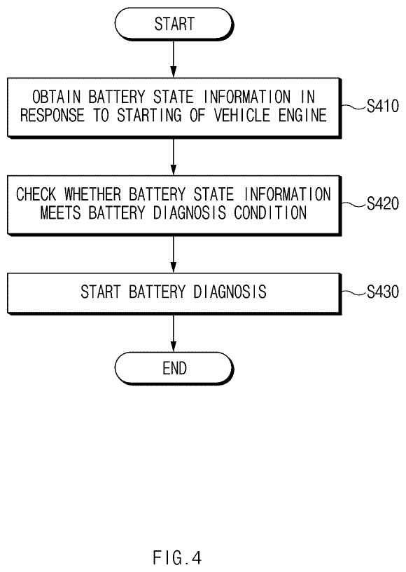

The battery diagnosis procedures shown in FIG. 3 may be performed when a preset battery diagnosis condition is satisfied. The battery diagnosis condition may be set to a condition in which the charging current of a normal battery is maintained high. According to an embodiment, the battery diagnosis may be performed when the battery diagnosis condition is met, thereby preventing a normal battery from being determined as a defective battery. The battery diagnosis condition is described with reference to FIG. 4 below.

FIG. 4 is a flowchart illustrating a battery diagnosis condition according to an embodiment of the present disclosure. FIG. 4 may be intended to illustrate prerequisites for entering the battery diagnosis procedure shown in FIG. 3. The procedures shown in FIG. 4 may be controlled by a processor. A method of entering a battery diagnosis procedure is described with reference FIG. 4 below.

In operation S410, the processor 100 may obtain battery state information in response to starting a vehicle engine.

The battery state information may be provided from the sensor device 50 or the control device 20. The battery state information may include at least one of charging history information of the battery 10, a state of charge (SOC) of the battery 10, or measurement information of the battery 10.

In operation S420, the processor 100 may check whether the battery state information meets the battery diagnosis condition.

The battery diagnosis condition may be determined using at least one of i) the number of consecutive charging times of the battery 10, ii) the SOC of the battery 10, iii) the voltage of the battery 10, iv) the temperature of the battery 10, or v) a combination thereof.

For example, the processor 100 may check the number of consecutive charging times of the battery 10 from the charging history information of the battery 10. The processor 100 may determine that a first condition is satisfied based on the fact that the number of consecutive charging times of the battery 10 is less than a reference number.

The reason for determining the battery diagnosis condition based on the number of charging times may be to detect the battery 10 in which sulfation reaction of the battery 10 has occurred during the battery diagnosis process. The sulfation reaction may mean that the battery 10 is left in a low SOC state and the active material inside the battery 10 hardens. The active material of the battery 10 that has undergone a sulfation reaction may be activated by repeatedly charging the battery. Therefore, in the battery 10 with a small number of consecutive charges, there is a possibility that the active material may be activated when charging is repeated. To the contrary, when the battery 10 that has undergone a sulfation reaction has already had a large number of consecutive charges, because the active material may not be activated even when charging is repeated, the battery 10 may be excluded from battery diagnosis.

In addition, the processor 100 may check the SOC of the battery 10 and determine that the battery diagnosis condition is satisfied based on the fact that the SOC of the battery 10 is less than or equal to the reference value. The charging performance of the battery 10 may vary depending on the SOC of the battery 10. The higher the SOC of the battery 10, the lower the charging current of the battery 10 may appear. Accordingly, the processor 100 may determine that the second condition is satisfied when the SOC of the battery 10 is less than or equal to the reference value.

In addition, the processor 100 may check the measured voltage of the battery 10 and determine that the battery diagnosis condition is satisfied based on the fact that the measured voltage of the battery 10 is higher than or equal to the reference voltage. While the battery 10 is charged, the measured voltage of the battery 10 may be equal to that of the charging device 9. When the charging voltage is low, the potential difference between the battery 10 and the charging device 9 may be low, so charging may not be smooth. Accordingly, the processor 100 may determine that the third condition is satisfied when the measured voltage of the battery 10 is higher than or equal to the reference voltage.

In addition, the processor 100 may check the temperature of the battery 10 and determine that the fourth condition is satisfied based on the fact that the temperature of the battery 10 is higher than or equal to the reference temperature. Because the charging performance of the battery 10 deteriorates at low temperatures, the accuracy of diagnosing the performance of the battery 10 may decrease at low temperatures. Accordingly, the processor 100 may determine whether the fourth condition is satisfied based on the temperature of the battery 10. The temperature of the battery 10 may be determined based on the outside temperature of the vehicle VEH.

In operation S430, the processor 100 may perform the battery diagnosis when the battery diagnosis condition is met. For example, the processor 100 may perform the battery diagnosis when at least one of the first to fourth conditions is met. In addition, in order to improve the accuracy of battery diagnosis, the processor 100 may perform the battery diagnosis when all of the first to fourth conditions are met.

The battery diagnosis may be initiated through an operation of obtaining a measured current value.

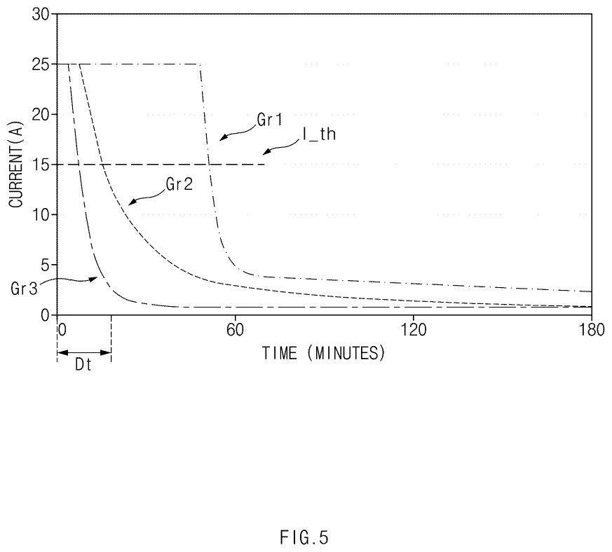

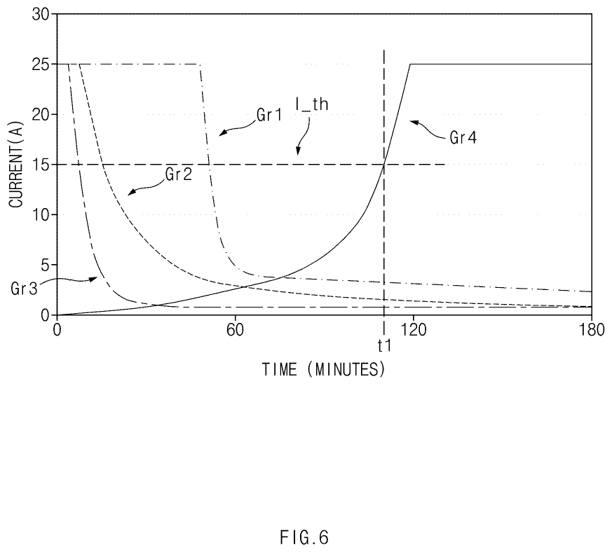

Hereinafter, the basis for determining a battery defective state by the processor based on the charging current value is described with reference to FIGS. 5 and 6.

FIG. 5 is a diagram illustrating the changes in charging currents of a normal battery and a defective battery. A first graph Gr1 may be a graph illustrating the change in a charging current of a normal battery, and a second graph Gr2 and a third graph Gr3 may be graphs illustrating the change in a charging current of a defective battery.

As shown in the first graph Gr1, the battery 10 in a normal state may be close to a fully charged state after being charged for about 50 minutes, and it may be understood that the charging current rapidly decreases after charging is completed.

As in the second graph Gr2 and the third graph Gr3, it may be understood that the batteries 10 in a defective state are only charged smoothly with a great charging current only at the beginning of charging, and the current decreases rapidly after a short time period. Batteries showing charging current patterns such as the second graph Gr2 and the third graph Gr3 may be batteries in which the active material that generates electricity is almost consumed due to the large number of charging and discharging. Batteries with depleted active materials may be defective batteries with drastically reduced battery capacity, and performance degradation may not be restored.

Therefore, a normal battery and a defective battery may be distinguished based on the charging current obtained while the battery 10 is charged during a diagnosis period Dt for a specified time period.

FIG. 6 is a diagram illustrating a method of detecting an activatable battery.

In FIG. 6, the first graph Gr1 may be a graph showing the change in a charging current of a normal battery, and the second graph Gr2 and the third graph Gr3 may be graphs showing the changes in charging currents of a defective battery. The fourth graph Gr4 shows the charging current of a battery in which the active material may be activated even though the sulfation reaction is performed.

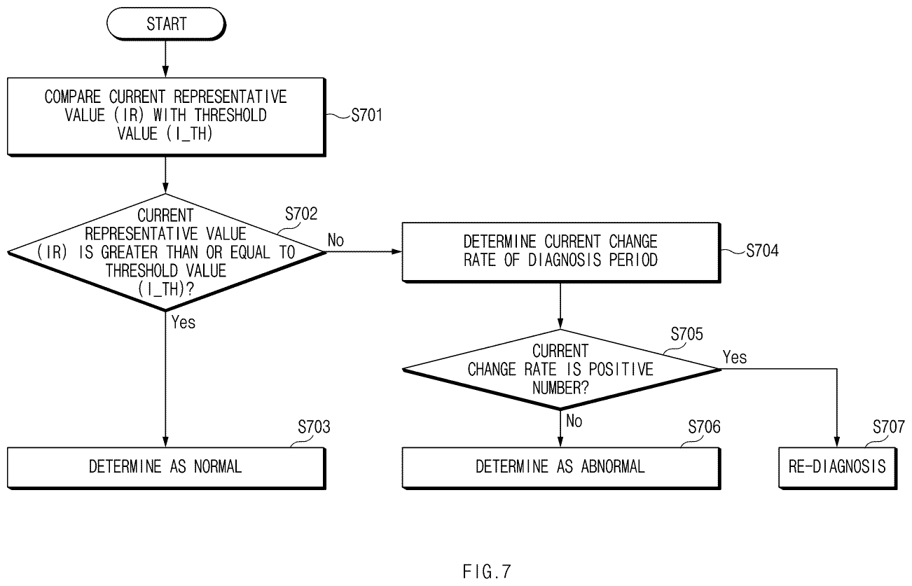

As shown in the fourth graph Gr4, when charging of batteries that have undergone a sulfation reaction continues as shown in FIG. 4, the active material may be activated and charging performance may be maintained at the normal battery level. As described above, an example of detecting a battery whose charging performance has deteriorated due to a temporary sulfation reaction but whose charging performance may be recovered is described with reference to FIG. 7 below.

FIG. 7 is a flowchart illustrating a method of managing a battery according to another embodiment of the present disclosure. FIG. 7 illustrates an example of detecting a battery whose charging performance may be restored.

In operation S701, the processor 100 may compare the current representative value Ir with a threshold value “I_th”.

In operation S702, the processor 100 may determine whether the current representative value Ir is greater than or equal to the threshold value I_th.

In operation S703, the processor 100 may determine that the battery 10 is normal based on the fact that the current representative value Ir is greater than or equal to the threshold value I_th.

In operation S704, the processor 100 may determine the current change rate of the diagnosis period. The current change rate may be an average change rate obtained based on the deviation between the charging current at the end timing and the charging current at the start timing of the diagnosis period. Alternatively, the current change rate may be an average change rate for some section within the diagnosis period. Some sections may include the end timing of the diagnosis period.

In operation S705, the processor 100 may determine whether the current change rate is a positive number. In operation S706, the processor 100 may determine a re-diagnosis when the current change rate is a positive number.

As shown in the fourth graph Gr4 shown in FIG. 6, when the magnitude of the charging current increases during the diagnosis period, the processor 100 may determine that the current change rate is a positive number.

The fourth graph Gr4 may represent the charging current of the battery that may restore normal performance as the active material is activated as charging continues.

In the initial stage after charging starts, the charging current of the fourth graph Gr4 may be determined to be less than the threshold value I_th, but after the first timing t1, the charging current may be greater than or equal to the threshold value I_th. As described above, because the battery whose charging performance is likely to recover has a positive current change rate as shown in the fourth graph Gr4, the processor 100 may determine whether to re-diagnose based on operation S705.

Because the re-diagnosis in operation S707 may mean extending the charging time of the battery 10 or increasing the number of charging times, the charging current may gradually decrease in the battery whose performance is recovered as shown in the fourth graph Gr4 in FIG. 6. In addition, when the re-diagnosis is performed after the first timing t1, the processor 100 may determine that the battery whose performance is restored is in a normal state.

In operation S707, when the current change rate is not positive number, the processor 100 may determine that the battery is abnormal. This is because, as shown in the second graph Gr2 and the third graph Gr3 of FIG. 6, batteries whose current change rate is not positive number may be determined as defective batteries.

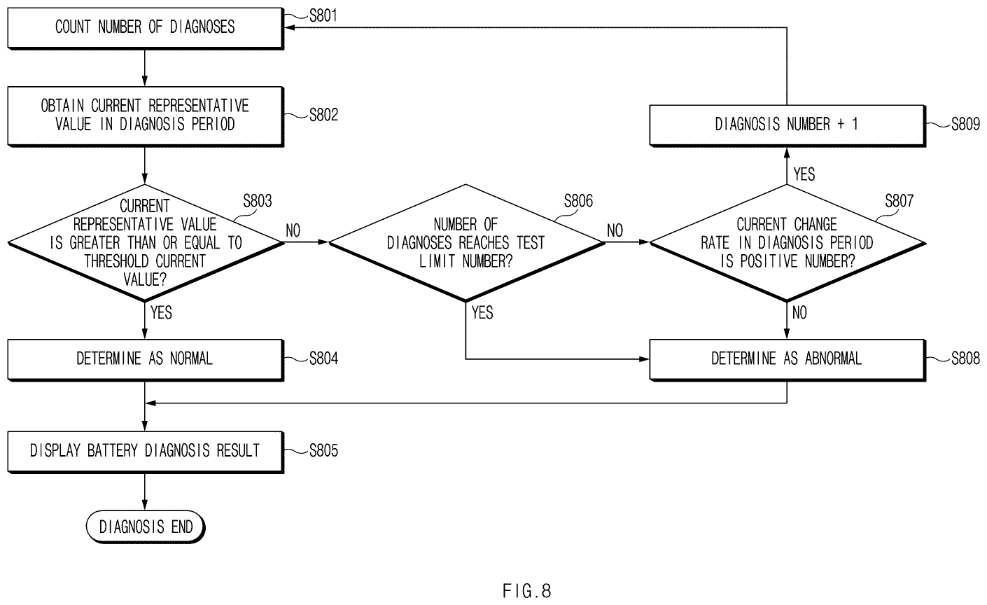

FIG. 8 is a flowchart illustrating a battery management method according to another embodiment of the present disclosure. FIG. 8 illustrates a process controlled by a processor. A method of managing a battery according to another embodiment of the present disclosure is described with reference to FIG. 8 below.

In operation S801, the processor 100 may count the number of diagnoses. When entering the first diagnosis, the number of diagnoses may be 1. When entering operation S801 after operation S809, the number of diagnoses may be increased by 1.

In operation S802, the processor 100 may obtain the current representative value in the diagnosis period. A method of obtaining the current representative value may use operation S320 shown in FIG. 3.

In operation S803, the processor 100 may determine whether the current representative value is greater than or equal to a threshold current value. The threshold may be preset.

In operation S804, the processor 100 may determine that the battery 10 is normal based on the fact that the current representative value is greater than or equal to the threshold value.

In operation S805, the processor 100 may display the battery diagnosis result. The battery diagnosis result may indicate whether the battery 10 is normal or defective. The battery diagnosis result may be displayed through a diagnostic device connected to the vehicle VEH or a display inside the vehicle VEH.

In operation S806, the processor 100 may determine whether the number of diagnoses reaches a test limit number. The test limit number may be preset to 1 or more and may be intended to limit the number of diagnoses.

When the test limit number is set to 1, the diagnosis period is limited to one time, and when operation S806 is entered, it may proceed to operation S808. In other words, when the test limit number is set to 1, in response to the current representative value being less than the threshold current in S803, the processor 100 may determine that the battery 10 is defective.

When the test limit number is 2 or more and the number of diagnoses is less than the test limit number, operation S807 may be performed.

In operation S807, based on the fact that the number of diagnoses is not reached the test limit number, the processor 100 may determine whether the current change rate in the diagnosis period is a positive number. Operation S807 may be the same as operation S705.

In operation S808, when the number of diagnoses reaches the test limit number or the current change rate in the diagnosis period is not a positive number, the processor 100 may determine that the battery 10 is abnormal.

In operation S809, based on the fact that the current change rate in the diagnosis period is a positive number, the processor 100 may determine re-diagnosis. Accordingly, the processor 100 may increase the diagnosis count by 1 and then enter the operation S801.

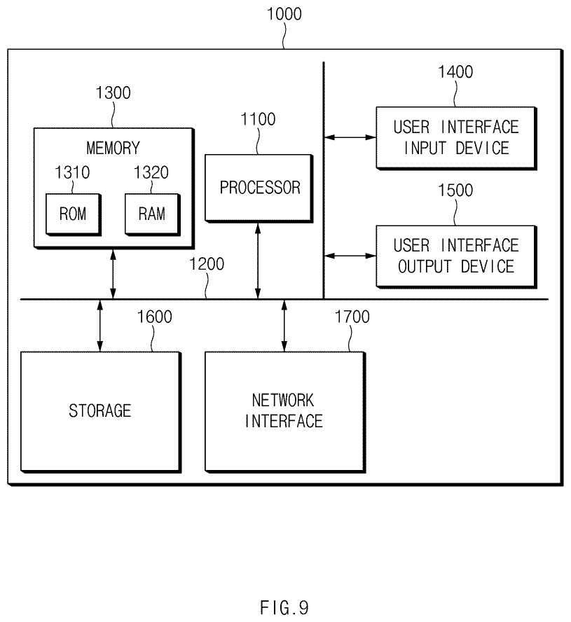

FIG. 9 is a block diagram illustrating a computing system according to an embodiment of the present disclosure.

Referring to FIG. 9, a computing system 1000 may include at least one processor 1100, a memory 1300, a user interface input device 1400, a user interface output device 1500, storage 1600, and a network interface 1700 connected through a bus 1200.

The processor 1100 may be a central processing unit (CPU) or a semiconductor device that processes instructions stored in the memory 1300 and/or the storage 1600. The memory 1300 and the storage 1600 may include various volatile or nonvolatile storage media. For example, the memory 1300 may include a read only memory (ROM) and a random access memory (RAM).

Accordingly, the processes of the method or algorithm described in relation to the embodiments of the present disclosure may be implemented directly by hardware executed by the processor 1100, a software module, or a combination thereof. The software module may reside in a storage medium (that is, the memory 1300 and/or the storage 1600), such as a RAM memory, a flash memory, a ROM memory, an EPROM memory, an EEPROM memory, a register, a hard disk, solid state drive (SSD), a detachable disk, or a CD-ROM.

The exemplary storage medium is coupled to the processor 1100, and the processor 1100 may read information from the storage medium and may write information in the storage medium. In another method, the storage medium may be integrated with the processor 1100. The processor and the storage medium may reside in an application specific integrated circuit (ASIC). The ASIC may reside in a user terminal. In another method, the processor and the storage medium may reside in the user terminal as an individual component.

According to the embodiments of the present disclosure, because the battery is diagnosed based on the diagnosis conditions, the time required for diagnosis may be reduced while increasing the accuracy of diagnosis.

In addition, according to the embodiments of the present disclosure, it is possible to classify batteries whose performance has recovered from a temporarily deteriorated state, thereby preventing the batteries from being unnecessarily determined to be defective.

In addition, various effects that are directly or indirectly understood through the present disclosure may be provided.

Although some embodiments of the present disclosure have been described for illustrative purposes, those having ordinary skill in the art should appreciate that various modifications, additions and substitutions are possible, without departing from the scope and spirit of the disclosure.

Therefore, the embodiments disclosed in the present disclosure are provided for the sake of descriptions, not limiting the technical concepts of the present disclosure, and it should be understood that such embodiments are not intended to limit the scope of the technical concepts of the present disclosure. The protection scope of the present disclosure should be understood by the claims below, and all the technical concepts within the equivalent scopes should be interpreted to be within the scope of the right of the present disclosure.

What is claimed is:

1. An apparatus comprising:
a sensor configured to measure a current of a battery; and
a processor connected to the sensor and configured to:
obtain a charging current value per unit time through the sensor in a diagnosis period during which the battery is charged;
obtain a current representative value of the charging current values; and
determine whether the battery is defective based on the current representative value.

2. The apparatus of claim 1, wherein the processor is configured to:
receive battery state information from the sensor; and
obtain the charging current value based on the battery state information and a predetermined battery diagnosis condition.

3. The apparatus of claim 2, wherein the battery state information includes battery charging history information, and
wherein the processor is configured to obtain the charging current value when a number of consecutive charging times of the battery in the charging history information is less than a reference number.

4. The apparatus of claim 2, wherein the battery state information includes state of charge (SOC) of the battery, and
wherein the processor is configured to obtain the charging current value when the remaining capacity value of the battery is less than or equal to a reference value.

5. The apparatus of claim 2, wherein the battery state information includes a measured voltage of the battery, and
wherein the processor is configured to obtain the charging current value when the measured voltage of the battery is greater than or equal to a reference voltage.

6. The apparatus of claim 1, wherein the processor is configured to obtain an average value, a minimum value, or a maximum value of the charging current as the current representative value.

7. The apparatus of claim 1, wherein the processor is configured to determine that the battery is in a normal state based on the current representative value being greater than or equal to a threshold value.

8. The apparatus of claim 7, wherein the processor is configured to:
determine a rate of change of the charging current value in the diagnosis period when the current representative value is less than the threshold value; and
determine whether to perform a re-diagnosis based on the rate of change of the charging current value.

9. The apparatus of claim 8, wherein the processor is configured to determine whether to perform the re-diagnosis based on that the rate of change of the charging current value is a positive number.

10. The apparatus of claim 8, wherein the processor is configured to:
perform the re-diagnosis within a preset limited number of times; and
determine that the battery is in a defective state when the current representative value obtained within the limited number of times is less than the threshold value.

11. A method comprising:
obtaining, by a processor, a charging current value per unit time through a sensor during a diagnosis period during which a battery is charged;
determining, by the processor, a current representative value of the charging current values; and
determining, by the processor, whether the battery is defective based on the current representative value.

12. The method of claim 11, wherein obtaining the charging current value comprises:
receiving battery state information from the sensor; and
obtaining the charging current value corresponding to the battery state information meeting a battery diagnosis condition.

13. The method of claim 12, wherein the battery state information includes battery charging history information, and
wherein obtaining the charging current value comprises:
confirming a number of consecutive charging times of the battery from the charging history information; and
obtaining the charging current value corresponding to the number of consecutive charging times of the battery being less than a reference number.

14. The method of claim 12, wherein the battery state information comprises state of charge (SOC), and
wherein obtaining the charging current value is performed corresponding to the remaining capacity value of the battery being less than or equal to a reference value.

15. The method of claim 12, wherein the battery state information comprises a measured voltage of the battery, and
wherein obtaining the charging current value is performed corresponding to the measured voltage of the battery being greater than or equal to a reference voltage.

16. The method of claim 11, wherein obtaining the current representative value of the charging current values comprises obtaining an average value, a minimum value, or a maximum value of the charging current as the current representative value.

17. The method of claim 11, wherein determining whether the battery is defective comprises determining that the battery is normal based on the current representative value being greater than or equal to a threshold value.

18. The method of claim 17, wherein determining whether the battery is defective comprises:
determining a rate of change of the charging current value in the diagnosis period corresponding to the current representative value being less than the threshold value; and
determining whether to perform a re-diagnosis based on the rate of change of the charging current value.

19. The method of claim 18, wherein determining whether to perform the re-diagnosis comprises determining whether to perform the re-diagnosis based on that the rate of change of the charging current value is a positive number.

20. The method of claim 18, wherein determining whether to perform a re-diagnosis comprises:
performing the re-diagnosis within a preset limited number of times; and
determining that the battery is in a defective state based on the current representative value obtained, within the limited number of times, being less than the threshold value.
